(19) United States
(12) Patent Application Publication
(10) Pub. No.: US 2008/0169570 A1
(43) Pub. Date: Jul. 17, 2008

(54) METHOD FOR MANUFACTURING A SEMICONDUCTOR DEVICE USING A REFLOW SPUTTERING TECHNIQUE

(75) Inventor: Masayoshi SAITO, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 11/972,257

(22) Filed: Jan. 10, 2008

(30) Foreign Application Priority Data
Jan. 11, 2007 (JP) 2007-003701

(51) Int. Cl. H01L 23/48; H01L 21/4763

(52) U.S. Cl. 257/774; 438/636; 257/E21.495; 257/E23.01

(57) ABSTRACT

An AlCu film is formed by simultaneously depositing AlCu within a via hole and on top of an interlayer dielectric film. The surface of the AlCu film is polished using a CMP process, and a TiN antireflection layer is formed thereon. The TiN antireflection layer having a flat surface prevents halation during pattering the interconnections including the AlCu film, thereby preventing ingress of etching solution during a subsequent wet etching process.

This application is based upon and claims the benefit of priority from Japanese patent application No. 2007-003701, the disclosure of which is incorporated herein in its entirety by reference.

### BACKGROUND OF THE INVENTION

1. Field of the Invention

The present invention relates to a semiconductor device and a method for manufacturing the semiconductor device. More particularly, the present invention relates to a semiconductor device having a multilayer interconnection structure and a method for manufacturing such a semiconductor device.

2. Description of the Related Art

There have been increasing demands for semiconductor devices to fabricate small-width, high-density and low-resistance interconnections to obtain a multilayer interconnection structure including aluminum (Al) or Al alloy including Al as a main component thereof. Meeting such demands requires embedding an interconnection material with a higher embedding performance into a small-diameter through-hole or via hole, and increasing the thickness of the Al interconnections to be formed on an insulating film.

For example, as described in Patent Publication JP-1995-263589-A1, the process of forming the multilayered Al interconnections includes a technique of: setting a substrate temperature at 150 degrees C. or higher; using a CVD (Chemical Vapor Deposition) technique and sputtering technique to simultaneously embed Al interconnection material into via holes and deposit an Al interconnection layer onto an insulating film; and then polishing the top portion of the Al interconnection layer by use of a CMP (Chemical Mechanical Polishing) process in order to form a desired thickness. A reflow sputtering technique is also known as the technique for forming the multilayered Al interconnections by setting a substrate temperature at for example, 400 degrees C. and causing the Al interconnection material to reflow. In this reflow sputtering technique, if the via holes have a smaller diameter, it is essential to set the substrate temperature higher than usual to enhance the embedding performance of the Al interconnection material. On the other hand, an excessively higher substrate temperature enhances the grain growth of Al in the Al interconnection material, with a problem that the surface roughness becomes larger in an attempt of forming an equal thickness.

As described above, if the Al interconnection material is deposited by using the reflow sputtering technique at a high temperature, via plugs or via plugs adapted to fill the through-holes and the Al interconnection layer located on the interlayer dielectric film are formed in a single process. In this technique, however, the depositing process is carried out by maintaining a higher substrate temperature of, for example, 390 degrees C. to 500 degrees C. level. Because of such a higher temperature, a large degree of roughness may be caused on the top surface of the Al interconnections. For example, if an AlCu alloy film having a thickness as large as 2 μm is formed by use of the reflow sputtering technique to form the Al interconnection layer, the surface roughness of the Al interconnection layer will be as large as 700 nm, for example. The large surface roughness may incur a halation to thereby cause a defective patterning in the subsequent photolithographic process. In addition, the surface roughness may incur ingress of etching solution into the wafer during a wet etching process subsequent to the photolithographic process. The etching solution may enter the semiconductor device and react with the Al interconnection material to generate a compound, which incurs a short-circuit failure between the interconnections.

### SUMMARY OF THE INVENTION

In view of the above, it is an object of the present invention to provide a method for manufacturing a semiconductor device, which is capable of reducing the surface roughness during the process for forming an interconnection layer having a relatively large thickness and via plugs within the through-holes, and thereby preventing occurrence of the defective patterning and short-circuit failure during the subsequent photolithographic process and wet etching process.

It is another object of the present invention to provide a semiconductor device manufactured by the process as described above.

The present invention provides a method for manufacturing a semiconductor device including: forming an interlayer dielectric film having a through-hole on a first interconnection pattern; depositing a via plug filling said through-hole and an interconnection layer on said interlayer dielectric film in a single step; polishing a top surface of said interconnection layer; forming an antireflection film on said polished surface of said interconnection layer; and patterning the antireflection film and the polished interconnection layer to form a second interconnection pattern.

The present invention also provides a semiconductor device including: a first interconnection pattern overlying a semiconductor substrate; an interlayer dielectric film having a through-hole through which a portion of the first interconnection pattern is exposed; a second interconnection pattern formed on the interlayer dielectric film and including a via plug filling the through-hole, the second interconnection pattern having a polished top surface; and an antireflection film formed on the second interconnection pattern.

The above and other objects, features and advantages of the present invention will be more apparent from the following description, referring to the accompanying drawings.

### BRIEF DESCRIPTION OF THE DRAWINGS

FIGS. 1A and 1B are sectional views of a semiconductor device, consecutively showing two stages of a process for manufacturing the same according to a first embodiment of the present invention.

FIGS. 2A to 2F are sectional views showing detailed steps of the stages of FIGS. 1A and 1B.

FIGS. 3A to 3D are sectional views of a semiconductor device, consecutively showing steps of a process for manufacturing the same according to a second embodiment of the present invention.

FIGS. 4A to 4C are sectional views of a semiconductor device, consecutively showing steps of a process for manufacturing the same according to a third embodiment of the present invention.

FIGS. 5A to 5C are sectional views of a semiconductor device, consecutively showing steps of a process for manufacturing the same according to a fourth embodiment of the present invention.

FIGS. 6A to 6C are sectional views of a semiconductor device, consecutively showing steps of a process for manufacturing the same according to a fifth embodiment of the present invention.

FIGS. 7A to 7D are sectional views of a semiconductor device, consecutively showing steps of a process for manufacturing the same according to a sixth embodiment of the present invention.

FIGS. 8A to 8D are sectional views of a semiconductor device, consecutively showing steps of a process for manufacturing the same according to a seventh embodiment of the present invention.

FIGS. 9A to 9F are sectional views of a semiconductor device, consecutively showing steps of a process for manufacturing the same according to a eighth embodiment of the present invention.

FIG. 10 is a sectional view of a semiconductor device in a variation of the above embodiment.

### DETAILED DESCRIPTION OF THE PREFERRED EMBODIMENTS

Now, exemplary embodiments of the present invention will be described with reference to accompanying drawings, wherein similar constituent elements are designated by similar reference numerals throughout the drawings.

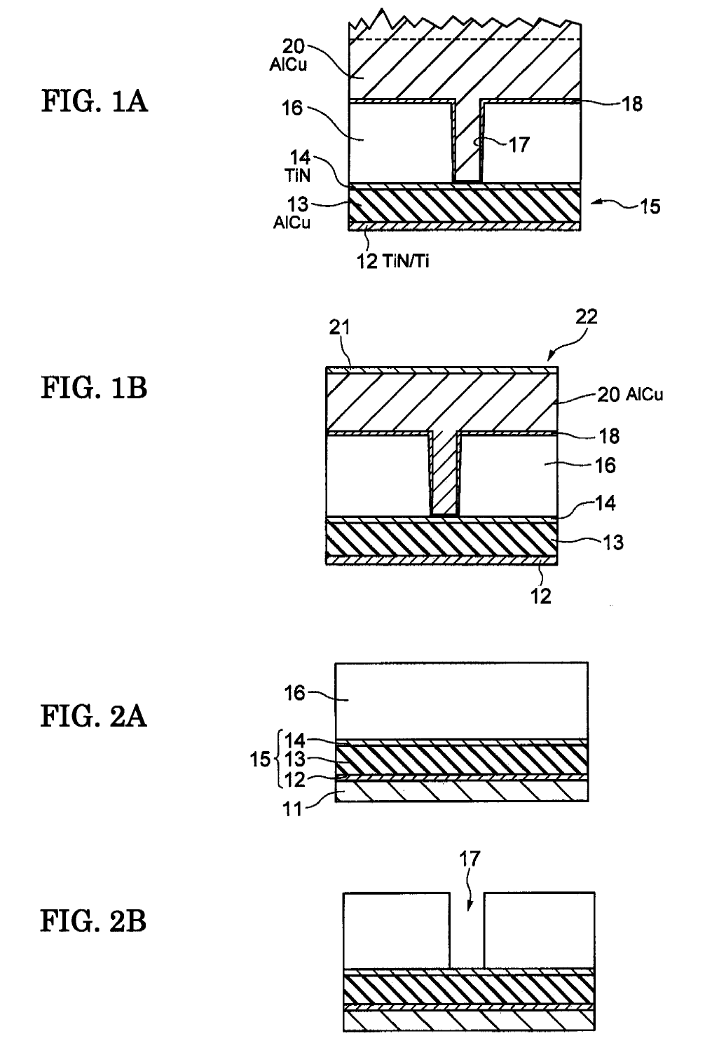

FIGS. 1A and 1B are sectional views of a semiconductor device, illustrating a process for forming an interconnection layer in a method according to a first embodiment of the present invention, in which the process for forming the interconnection layer is divided roughly into two stages. FIG. 1A shows a first stage in which via plugs and a second interconnection layer is deposited, whereas FIG. 1B shows a second stage in which an antireflection film is formed on the second interconnection layer and a patterning process has been performed thereon. In FIG. 1A, first interconnections (for example, first-layer interconnections) 15 are formed on a semiconductor substrate (not shown) via an interlayer dielectric film. The first interconnections 15 have a multilayer structure including a TiN antireflection layer 14, an AlCu film 13 and a TiN/Ti film 12, which are shown from the top in this order. An interlayer dielectric film 16 having therein via holes 17 is formed on the first interconnections 15.

In the process for forming the second interconnection layer (for example, second-layer interconnection layer), a Ti film configuring a barrier layer 18 is first formed within the via holes 17 and on the interlayer dielectric film 16. Subsequently, a hot-reflow sputtering technique is used to embed AlCu within the via holes 17 and deposit AlCu onto the interlayer dielectric film 16 at the same time, to thereby form an AlCu film 20 including via plugs. FIG. 1A shows the interconnection structure including the first interconnections and the second interconnection layer at this stage. Subsequently, the AlCu film 20 is polished for removal the top portion thereof by using a CMP process for obtaining a flat top surface. Thereafter, a TiN film configuring an antireflection layer 21 is deposited, followed by patterning thereof using a photolithographic technique, to thereby form the second interconnections 22. FIG. 1B shows the interconnection structure at this stage. The Ti barrier layer 18 reacts with Al at a high temperature to form an AlTix alloy in the reflow sputtering process for the AlCu film 20. The Ti barrier layer 18 turns into a wetting layer at this reflow step to increase the fluidity of AlCu. The TiN antireflection layer 21 has a function to prevent a halation from occurring in the patterning of the second interconnections 22, and a function to prevent an etchant from penetrating through the second interconnections 22.

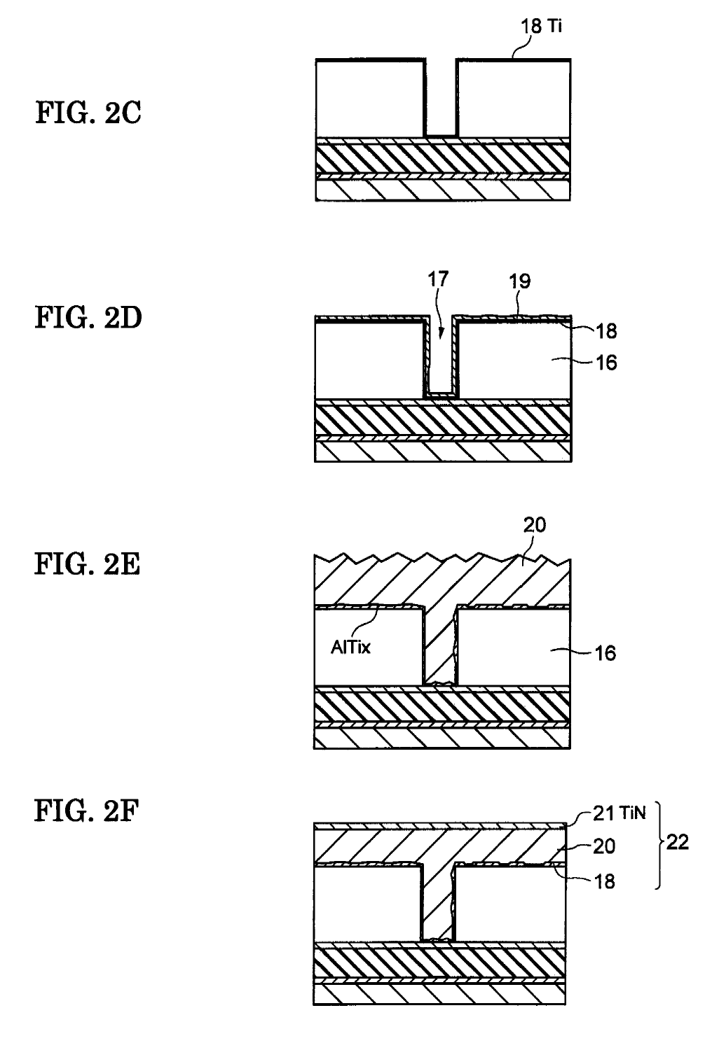

Now detailed description will be given of the above-described process with reference to the steps of FIGS. 2A through 2F.

### (1) Formation of First Interconnections

On a surface portion of a semiconductor (Si) substrate (not illustrated), a shallow-trench-isolation (STI) structure, wells and transistors are formed, and a borophosphosilicate glass (BPSG) film is deposited over the resulting structure. The BPSG film is then subjected to a heat treatment in a steam ambient to cause the BPSG film to reflow so as to obtain a flat surface. A non-doped SiO₂ film is deposited on the BPSG film by using a plasma-enhanced CVD process, and the resultant insulating layer is then polished by means of a CMP process, to form a first interlayer dielectric film 11 shown in FIG. 2A. Next, via holes (not illustrated) are formed in the first interlayer dielectric film 11, and tungsten (W) or the like is embedded therein to form via plugs. Subsequently, the first interconnections 15 including the TiN antireflection layer 14, AlCu film 13, and TiN/Ti film 12 are formed. During the process for forming the first interconnections 15, the substrate temperature is set at, for example, 250 degrees C. to heat the first interconnections 15 in an Ar ambient (at 8 Torr) for 60 seconds for achieving degassing of the first interconnections.

In the step of forming the first interconnections 15, first, the entire substrate (wafer) is introduced in an Ar-sputtering chamber and subjected to sputter etching of the first interlevel dielectric film by using Ar plasma for removing an equivalent oxide thickness (EOT) of 10 nm. Then, the wafer is transferred to a Ti-sputtering chamber, where the substrate temperature is set at 200 degrees C., to deposit a Ti film up to a thickness of 20 nm. Subsequently, the wafer is transferred to a TiN-sputtering chamber to deposit a TiN film up to a thickness of 30 nm by using a reactive sputtering technique, which introduces therein Ar and nitrogen for reaction. Thus, the TiN/Ti layer 12 is obtained. The resultant wafer is taken out from the chamber and subjected to a wet-cleaning treatment for the purpose of removing a variety of particles caused in the previous steps. Then, the wafer is introduced in a sputtering chamber and heated at a substrate temperature of 100 degrees C. in an Ar ambient at 8 Torr for 60 seconds for degassing. Thereafter, the wafer is subjected to an Al sputtering process at a substrate temperature of 300 degrees C. to form the AlCu film 13 having a thickness of 270 nm. The wafer is then transferred to a TiN-sputtering chamber, wherein heat is not applied to the substrate, to form a TiN film having a thickness of 27 nm. The TiN film configures the TiN antireflection layer 14. Subsequently, by using a plasma-enhanced CVD technique, a 50-nm-thick SiO₂ film (not shown) to be used as a hard mask is formed, followed by forming a resist mask (not shown) thereon, which is then used for patterning using a dry etching technique to obtain the first interconnections 15.

### (2) Formation of Via Holes

By using a high-density plasma-enhanced CVD process, the second interlayer dielectric film 16 configured by SiO₂ is deposited on the first interconnections 15 and the gap therebetween. The top surface of the second interlayer dielectric film 16 is polished for planarization using a CMP process. This step is shown in FIG. 2A. Subsequently, the via holes 17 are formed using a dry etching process. The via holes 17 are 0.8 μm deep and has an aspect ratio of 2.5. In this example, the TiN antireflection layer 14 of the first interconnections 15 is left in the product. In the dry etching process, the via holes (or through-holes) 17 are formed in such a manner as to have the bottom end above the TiN antireflection layer 14 by using a specific selectivity of the etching. The TiN antireflection layer 14 left in the product has a function of avoiding disconnection of the first interconnections 15 caused by electromigration. This step is shown in FIG. 2B.

### (3) Embedding AlCu by Using Hot-Reflow Sputtering Technique

Subsequently, a degassing treatment is conducted for the resultant wafer at a substrate temperature of, for example, 350 degrees C. in an Ar ambient at 8 Torr for 60 seconds. Then, the wafer is introduced in the Ar-sputtering chamber to subject the substrate to a sputter etching of the same for an EOT of 20 nm. The degassing treatment is conducted to prevent release of gas in the hot-reflow sputtering process performed later. If a significant amount of gas is released therein, the reflow is difficult to achieve.

Thereafter, the wafer is transferred to the Ti-sputtering chamber, where the substrate is not heated, to form the Ti barrier layer 18 having a thickness of 20 nm (FIG. 2C). The Ti contained in the Ti barrier layer 18 acts to accelerate the reflow of AlCu by forming an alloy with Al in the hot-reflow sputtering process performed later. It is to be noted however that the AlTi alloy has a specific resistance higher than that of the AlCu alloy causing a higher line resistance. Therefore, it is necessary to take into consideration the higher line resistance in the design of the interconnections. More specifically, it is necessary to set a thickness of the Ti barrier layer 18 at a suitable value.

Subsequently, the wafer is transferred to an AlCu-sputtering chamber, where the substrate temperature is maintained at 200 degrees C., and a thin AlCu film 19 having a thickness of 250 nm is formed as a seed layer. The thickness is to be measured at a flat portion of the interlayer dielectric film 16. This step is shown in FIG. 2D. The sputtering target used herein is AlCu alloy containing 0.5 wt % Cu. The content of Cu may be arbitrarily selected; however, the content of 0.5 wt % Cu especially improves the electromigration resistance of the Al alloy interconnections. It is to be noted that an excessively higher content of Cu may incur a short-circuit failure in the interconnections due to the Cu residuals remaining after the patterning process. In this sputtering process, the AlCu film is embedded within the via holes 17 to an even and specified thickness. For this purpose, the substrate temperature is set at 300 degrees C. or lower for the purpose of not causing the reflow of AlCu. If the AlCu film 19 configuring the seed layer and having a smaller thickness is subjected to the reflow process at this stage, the resultant AlCu film 19 may have a discontinuous or ununiform profile. This tendency will be more prominent in the case of a smaller-diameter via holes and a higher aspect ratio of the via holes.

Thereafter, AlCu is further deposited by sputtering onto the AlCu seed layer 19 at a substrate temperature of 445 degrees C. for 180 seconds so as to obtain a film thickness of 350 nm for the AlCu film. In the sputtering process, embedding of AlCu within the via holes 17 and deposition of the AlCu film onto the flat top surface of the second interlayer dielectric film 16 are simultaneously carried out to form the AlCu film 20. In this process, the substrate temperature is set at a higher temperature so as to reduce the deposition rate while providing the fluidity for the AlCu being deposited. In this process, the AlCu interconnections configuring an interconnection layer is formed while embedding AlCu within the via holes 17. This step is shown in FIG. 2E. The substrate temperature of 445 degrees C. may be changed depending on the device to be manufactured. If the substrate temperature is higher than around 370 degrees C., the fluidity of AlCu will be prominent.

A higher temperature increases the fluidity, increases the grain diameter, and increases the surface roughness of the AlCu film. It should be noted to form the uniform profile of the AlCu film especially on the step portion and within the via holes 17 before the reflow processing. This is because a thin portion of the AlCu film at this stage causes agglomeration of AlCu particles in the middle stage of the reflow processing, which may prevent the embedding of AlCu from being perfected. More specifically, in the hot-reflow sputtering process, it is important to maintain an appropriate substrate temperature during the reflow sputtering and to form a uniform film of AlCu having an appropriate thickness before entering the reflow stage. The present embodiment in consideration of these points, uses conditions where the AlCu is embedded within via holes 17 having an aspect ratio as high as 5.6.

In the hot-reflow sputtering process, since the grain growth in Al is enhanced, the degree of the surface roughness of the AlCu film 20 is larger. The surface roughness of the AlCu film 20 depends upon the Ti barrier layer 18 used as an underlying layer, and upon the temperature during the hot-reflow sputtering of the AlCu film. The surface roughness is such that a difference of 15% to 25% is recognized in the height of the top surface on the entire profile in terms of ratio with respect to the thickness at the flat portion. For instance, assuming that the AlCu film 20 at the flat potion is 2 μm thick, a difference of around 0.5 μm or smaller may be observed in the height of the profile of the AlCu film. This surface roughness may significantly scatter the light incident thereto during the exposure process. Further, if the antireflection film is formed on the surface having such a surface roughness, the resultant antireflection film may have an uneven thickness. If the antireflection film has an excessively higher surface roughness, the overlying TiN film formed thereon may have pin holes, thereby incurring ingress of the wet etching solution and a defect in the resultant semiconductor device.

### (4) CMP of AlCu Film

In order to solve the above problems, a CMP process is introduced to remove the surface roughness of the AlCu film 20 to obtain a uniform thickness thereof CMP of the AlCu film 20 has achieved satisfactory results in a technical field of manufacturing aluminum ROM discs or the like. For example, as described in Patent Publication JP-2000-219874-A1, it is possible to use as a polishing agent a composition of water and abrasive (alumina or SiO₂) using basic aluminum sulfamate as a promotor. Under the conditions where micro pits do not exist and a mean surface roughness is equal to or below 1 to 2 nm, setting of a polishing rate of 40 to 250 nm/minute may be adopted.

The surface roughness of the AlCu film 20 formed using the hot-reflow sputtering technique may be removed using a CMP process for planarization by an amount of about 30% with respect to the thickness of the film deposited. The amount of polishing by the CMP process can be determined depending on the degree of the surface roughness.

### (5) Deposition of TiN Antireflection Layer

On the surface of the AlCu film 20 polished by the CMP process, an undesirable thin Al oxide film is formed. To remove the undesirable thin Al oxide film, a degassing process is first carried out by heating the Al oxide film at 100 degrees C. in an Ar ambient, followed by Ar-sputter etching to remove the Al oxide layer by a thickness of around 10 nm. In this process, a setting of matching is employed in order to generate plasma, taking into account reflective waves. Plasma etching may be carried out while changing a setting therein depending on the case where an SiO₂ film is formed on the surface of the AlCu film and the case where the AlCu film is formed on the entire surface in the sample at this stage.

Thereafter, the TiN film is deposited to a thickness of 27 nm by using a typical sputtering process without heating the substrate. A sectional view at this stage is shown in FIG. 2E The thickness of the TiN antireflection layer 21 resulting from the sputtering process is a design matter to be determined based on the reflectance etc. to be managed.

The TiN antireflection layer 21 in the present embodiment has a uniform surface by virtue of the uniform underlying layer. The TiN antireflection layer 21 has a function of reducing the reflectance of the surface of the AlCu film 20 from some 90% to about 10% with respect to ultraviolet ray. Further, in the photolithographic process, the TiN antireflection layer 21 can suppress ingress of the wet processing solution into the AlCu film 20. If the underlying layer has a large degree of surface roughness, the reflectance will be higher.

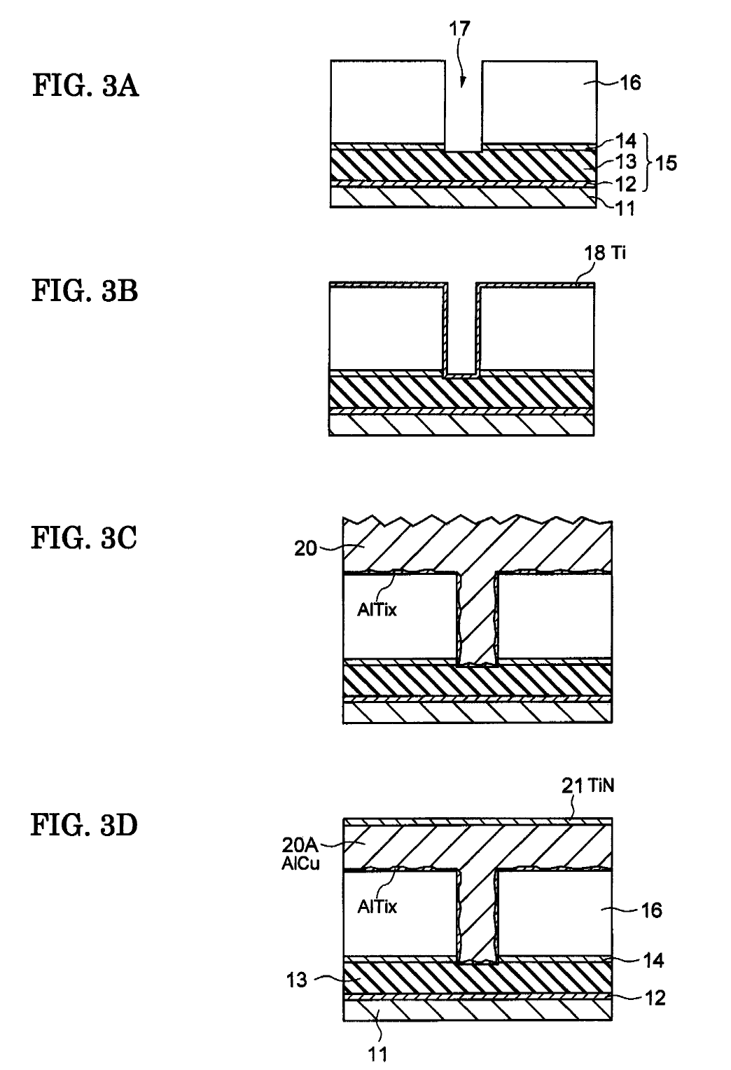

A method for manufacturing a semiconductor device according to a second embodiment of the present invention will now be described with reference to FIGS. 3A through 3D. First, as shown in FIG. 3A, the via holes 17 are formed after the step in which the second interlayer dielectric film 16 is formed. After forming the via holes 17, the TiN antireflection layer 14 of the first interconnections 15 is etched. By the etching, part of the AlCu film 13 is exposed. It is unnecessary to leave the thin TiN antireflection layer 14 after the etching of the via holes 17. Therefore, a high etch selectivity is not required.

Next as shown in FIG. 3B, the Ti barrier layer 18 is formed, and then, embedding of AlCu plugs and formation of an AlCu interconnection layer are simultaneously carried out (FIG. 3C). At this stage, the surface of the AlCu film 20 thus obtained has a significant degree of roughness, which is removed using a CMP process. Subsequently, the TiN antireflection layer 21 is formed on the uniform surface of the AlCu film 20 to obtain the structure shown in FIG. 3D.

In the second embodiment, since the TiN antireflection layer 14 of the first interconnections 15, which configures the underlying interconnection layer, is also etched during the pattern etching for the via holes 17, an Al—Ti alloy is generated in the AlCu film 20. This alloy has rough-hewn texture, and continuous parts and discontinuous parts coexist. For this reason, in the present embodiment, the contact resistance can be reduced as compared with the first embodiment, wherein the TiN antireflection layer 14 exists at an interface with the via plugs.

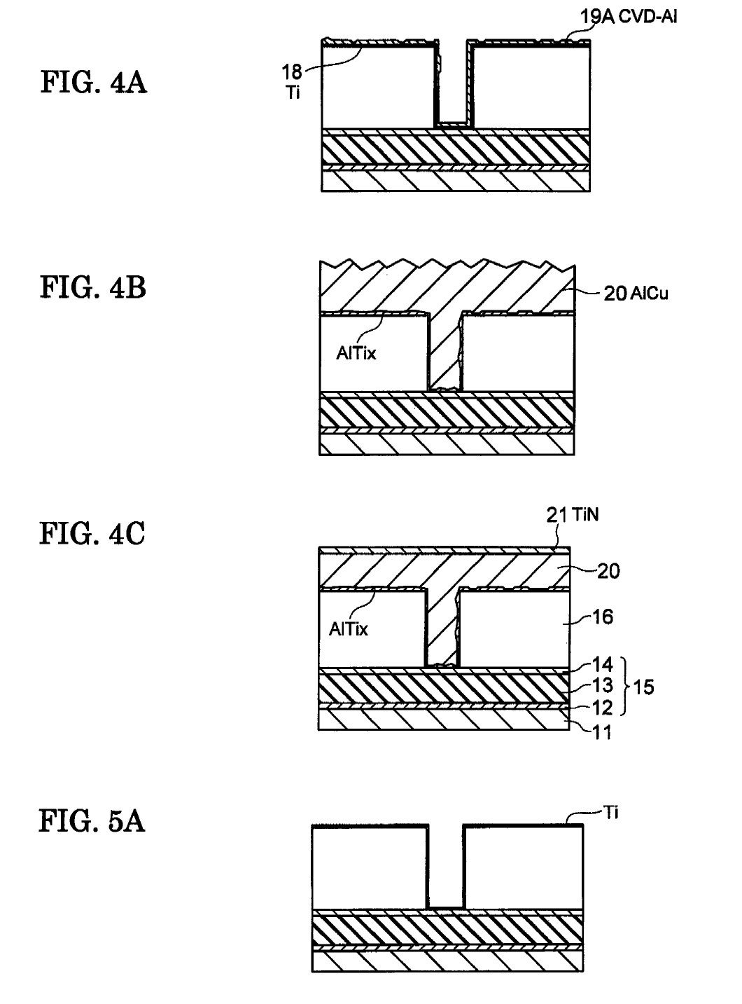

Next, a method for manufacturing a semiconductor device according to a third embodiment of the present invention will be described with reference to FIGS. 4A through 4C. In the first embodiment a high-directivity sputtering technique is used to form the thin AlCu film 19. However, in the present embodiment, a CVD process is used to form the thin Al film. As shown in FIG. 4A, the Ti barrier layer 18 for the second interconnection 22 is formed, and then the thin Al layer 19A is formed by a CVD process. This thin Al layer 19A is adapted to configure the seed layer for forming thereon a thick AlCu film 20 by use of the hot-reflow sputtering technique similarly to the first embodiment. The surface of the AlCu film 20 has a significant degree of roughness as shown in FIG. 4B. Therefore, the surface of the AlCu layer is polished by a CMP process for planarization, to form thereon the TiN antireflection layer 21 (FIG. 4C).

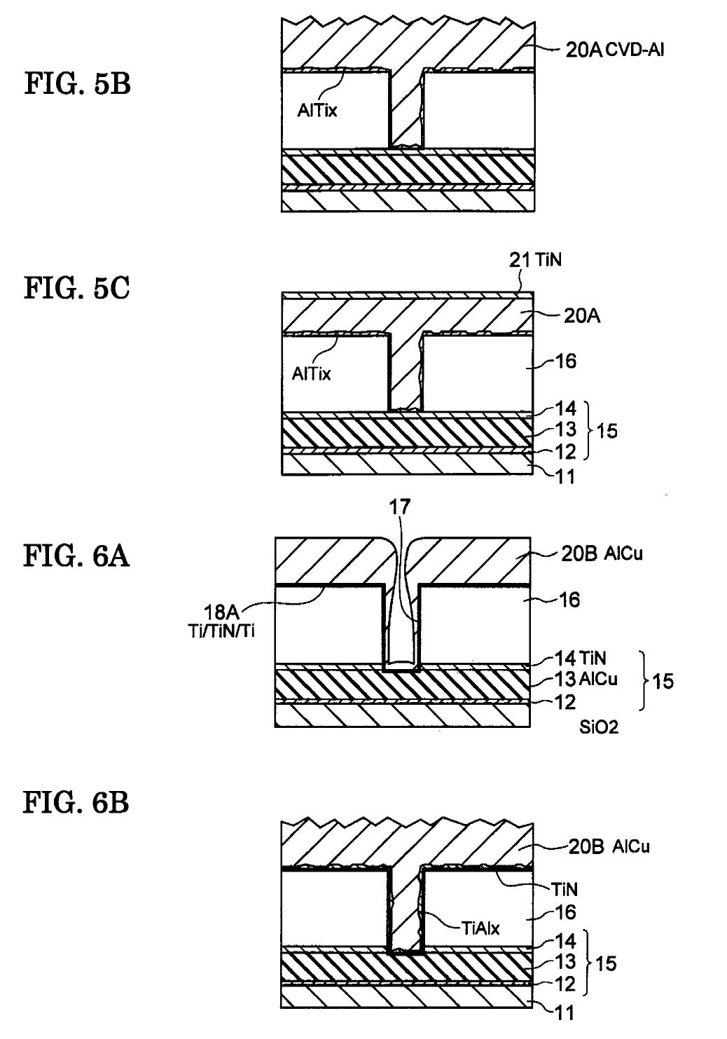

FIGS. 5A through 5C show a process for manufacturing a semiconductor device according to a fourth embodiment of the present invention. The present embodiment is similar to the third embodiment except that an Al layer 20A is formed by a CVD process instead of forming the AlCu film 20 by a hot-reflow sputtering technique in the third embodiment. In other words, the entire Al layer is formed by a CVD process instead of forming the AlCu film by using a high directivity sputtering technique or by using the hot-reflow sputtering technique in the first embodiment. Forming the Al layer by using a CVD process has a difficulty in doping the Al layer with Cu, whereby Cu is not doped especially in the embedded Al plugs and Al interconnection layer. To allow the Cu component to be introduced therein, a technique is adopted in which the Al layer 20A is partly or entirely formed by a CVD process before a thin Cu film is coated on the Al layer 20A, followed by a heat treatment to diffuse the Cu into the Al layer 20A.

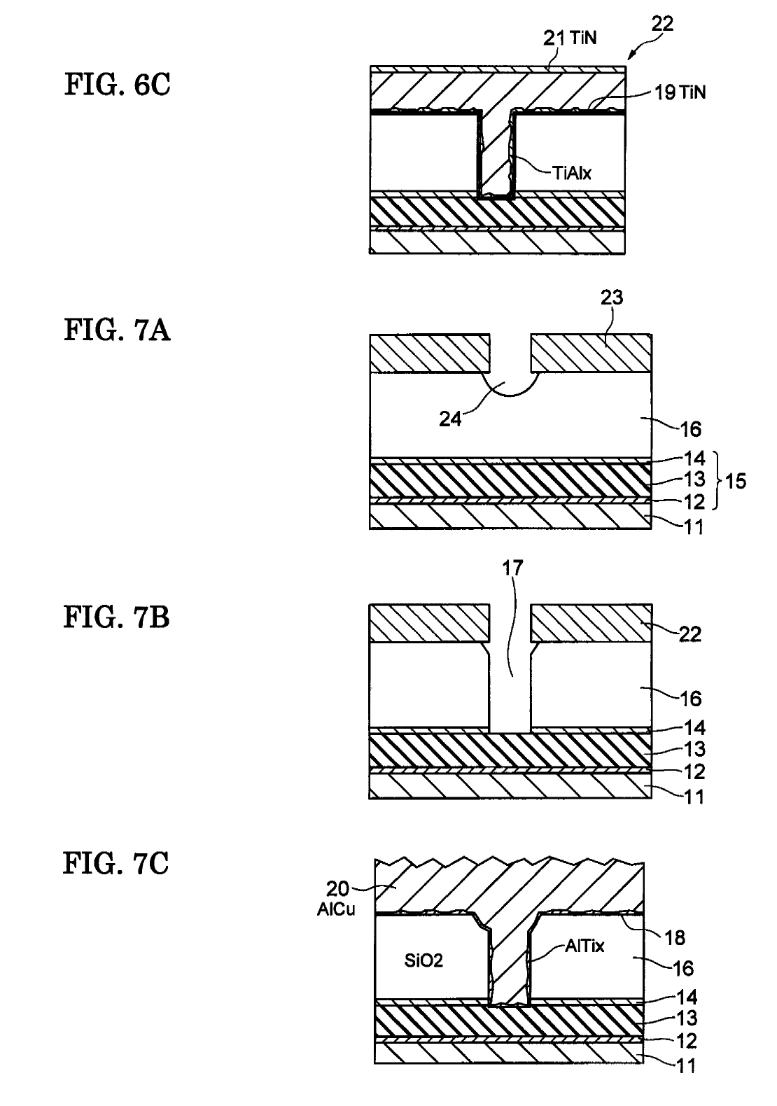

FIGS. 6A through 6C show a process for manufacturing a semiconductor device according to a fifth embodiment of the present invention. In the present embodiment, the barrier layer of the second interconnections includes Ti/TiN/Ti films, and an AlCu film 20B is embedded in the via holes 17 by using an annealing process. Specifically, as shown in FIG. 6A, the layer structure of the Ti/TiN/Ti films is formed as a barrier layer 18A. Due to the presence of the barrier layer 18A, it is possible to fill the via hole with a sputtered AlCu film, which has previously been formed, by using a heat treatment that does not require a high temperature (FIG. 6B). In this manner, by locating the barrier layer 18A that serves also as an adhesive layer (glue layer), the TiN film in the barrier layer 18A has a function of restricting absorption of AlCu, thereby removing the influence on the AlCu film 20B by the first interconnections 15. The Ti in the underlying layer of the barrier layer 18A prevents a higher contact resistance between the AlCu of the first interconnections 15 and the barrier layer 18A. The Ti in the overlying layer of the barrier layer 18A has a function of assisting the flow embedding of AlCu during the heat treatment. The layer structure of the Ti/TiN/Ti barrier layer is applicable to each of the embodiments as described before. In the following process, similarly to the embodiments described above, the AlCu film 20B is polished by a CMP process before forming thereon the TiN antireflection layer 21 (FIG. 6C).

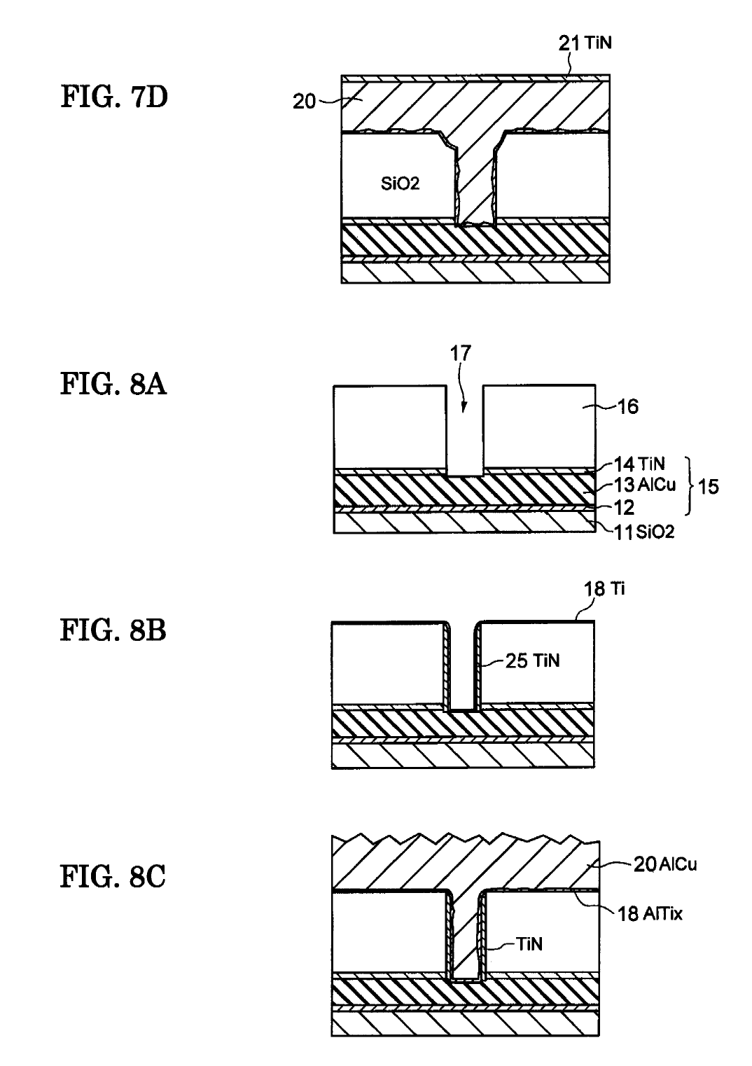

FIGS. 7A through 7C show a process for manufacturing a semiconductor device according to a sixth embodiment of the present invention. In the present embodiment, the via holes are formed in such a manner as to increase the diameter of the top opening of the via holes, whereby the effective aspect ratio of the via holes is reduced. This facilitates the embedding of the AlCu film into the via holes during the hot-reflow sputtering process. As shown in FIG. 7A, a photoresist film 23 is first formed on the interlayer dielectric film 16, and then a large-diameter opening 24 of the via holes is formed by an isotropic wet-etching process using a diluted hydrofluoric acid or a dry etching process using a surplus amount of fluorine radicals. Subsequently, the via holes 17 are formed by an anisotropic dry etching process while using the same photoresist mask 23 (FIG. 7B). Thereafter, the process is followed by formation of the Ti barrier layer 18, embedding of AlCu into the via holes by using a hot-reflow sputtering process, and formation of the AlCu interconnection layer (FIG. 7C). Further, the surface of the AlCu film 20 is polished by a CMP process before forming thereon the TiN antireflection layer 21 (FIG. 7D).

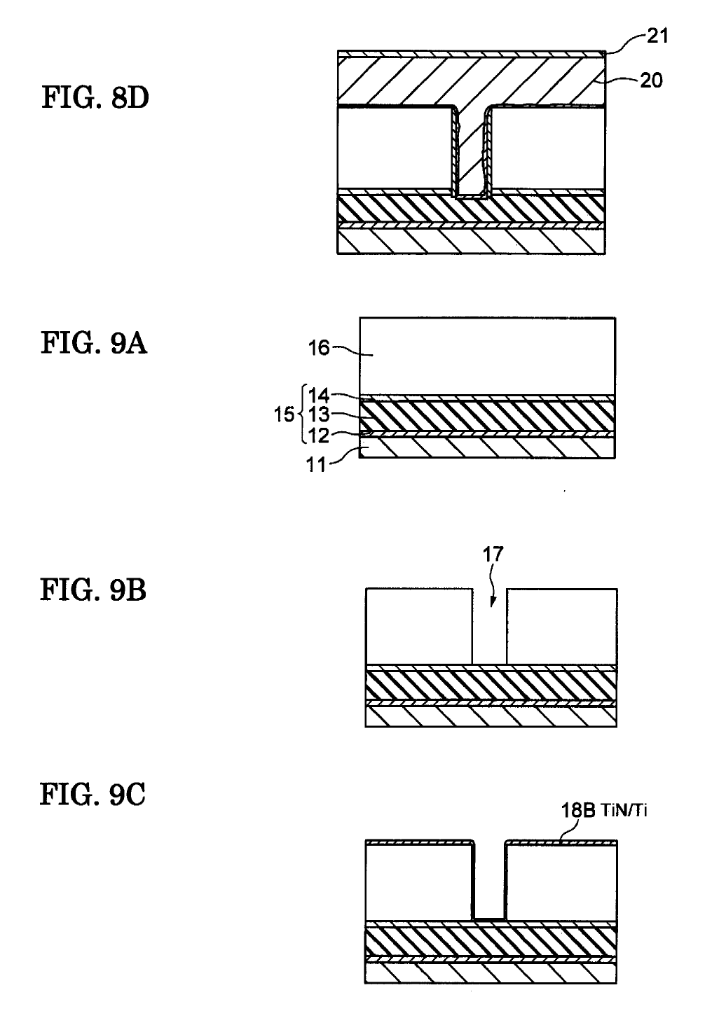

FIGS. 8A through 8D show a process for manufacturing a semiconductor device according to a seventh embodiment of the present invention. The present embodiment is an example where a sidewall film is formed on the inner surface of the via holes, followed by embedding the AlCu into the via holes by using a hot-reflow sputtering process. As shown in FIG. 8A, the via holes 17 are formed, a TiN sidewall film 25 is formed on the inner surface of the via holes 17, and then, the Ti barrier layer 18 is formed thereon (FIG. 8B). Subsequently, an AlCu film is formed using a high-directivity sputtering process, and thereafter, the AlCu film 20 is formed using the hot-reflow sputtering technique. The TiN sidewall film 25 is formed by deposition of TiN and etch-back thereof, whereby the inner surface of the via holes 17 is so formed as to have a forward-taper shape, which facilitates the embedding of AlCu by the hot-reflow process. It is to be noted that the sidewall film may be a conductor other than the TiN film, such as a high-melting-point metal or a nitride thereof, a metal-silicide, and the like.

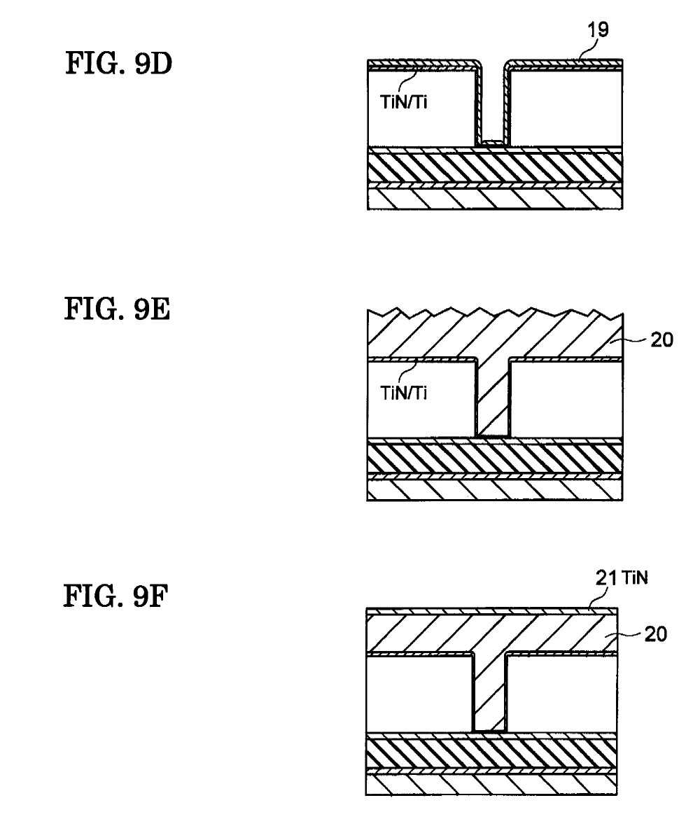

FIGS. 9A through 9F show a process for manufacturing a semiconductor device according to an eighth embodiment of the present invention. The process steps shown in FIGS. 9A and 9B are similar to those in the first embodiment. In the present embodiment, a barrier layer 18B for the second interconnections 22 includes TiN/Ti films (FIG. 9C). The process steps after the formation of the barrier layer 18B are similar to those in the first embodiment, and followed by: formation of the seed layer 19 (FIG. 9D); deposition of the AlCu film 20 (FIG. 9E); polishing of the AlCu film 20; and deposition of the TiN antireflection layer 21 (FIG. 9F). Similarly to the case of the Ti barrier layer 18, in the TiN/Ti films of the barrier layer 18B, the AlCu film has a (111) orientation as a main orientation. In this orientation, the grains of aluminum are most immobilized, which is suitable for securing the electromigration resistance. The structure in which TiN contacts with aluminum or an alloy thereof hardly creates an AlTix alloy. Therefore, the sheet resistance of the second interconnections may be maintained low.

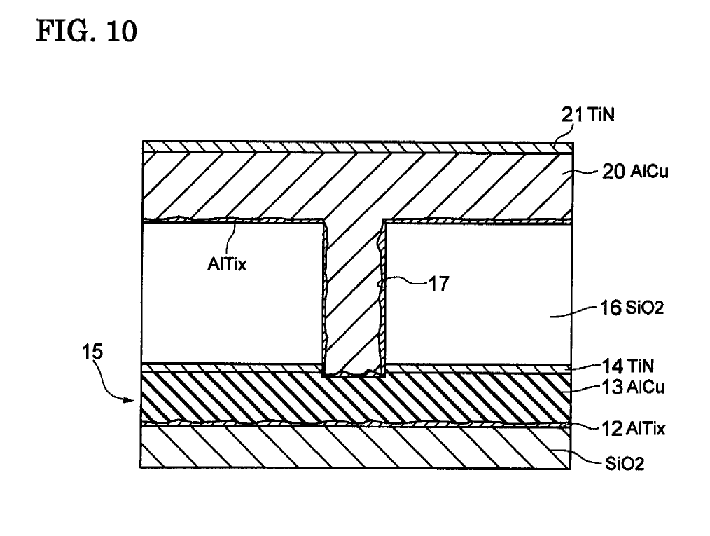

FIG. 10 is a modified example where the first and second interconnections each have a barrier layer configured by a single Ti film. The structure in which the Ti film contacts directly with aluminum or an alloy thereof provides a lower contact resistance. Which one of the Ti layer 18 and TiN/Ti layer 18B is to be selected may be determined based on priority: when priority is assigned to a lower contact resistance in the via plugs, a single Ti barrier layer may preferably be selected; when priority is assigned to a lower sheet resistance, the TiN/Ti barrier layer may preferably be selected. In this way, if there is a margin in the resistance in both the sheet resistance of interconnections and contact resistance of the plugs, there is no restriction, and it is arbitrary to select either one of the single Ti barrier and the TiN/Ti barrier layer.

As described above, in the present invention, since the surface roughness of aluminum is removed by a CMP process to form a uniform surface thereof. Thus, it is possible to form thereon an antireflection film having a uniform top surface. Accordingly, an abnormal reflection such as halation on the surface of the interconnection layer can be suppressed, which allows forming of a fine pattern in the pattering process. In addition, the antireflection film having a flat surface has a function to act as a resistance film to the wet processing. Therefore, the antireflection film has also an effect to avoid a short-circuit failure caused by the compound produced as a result of the ingress of a wet processing solution. In the above circumstances, it is possible to eliminate drawbacks that exist when the formation of the interconnections and embedding of the via holes are executed in a single process step. Further, by adopting the process of the embodiments, the manufacturing cost of the semiconductor device may be reduced.

According to the semiconductor device of the above embodiments and the semiconductor devices manufactured by the method of the above embodiments, the via plugs embedded within via holes and an interconnection layer formed on an interlayer dielectric film are simultaneously deposited by use of a hot-reflow sputtering technique. Therefore, the deposition of the interconnection material may be performed using a smaller number of process steps. In addition, since the surface of the interconnection layer is polished before an antireflection film is formed, the photolithographic process carried out after the hot-reflow sputtering process prevents a halation defect, with the result that a failure of patterning process hardly occurs. Further, since an etchant or wet processing solution is hardly to cause ingress to the interconnection layer, a pattering failure or a short-circuit failure in the interconnections does not occur. This provides an advantageous effect that a highly reliable semiconductor device can be obtained while reducing the number of steps in the fabrication process.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

For example, in the above embodiment, the first interconnections correspond to the first-layer interconnections and the second interconnections correspond to the second layer interconnections. However, the first interconnection may correspond to the second-layer interconnections and the second interconnections may correspond to the third-layer interconnections, for example. Alternatively, the first interconnection pattern may be formed within the semiconductor substrate, such as a diffused region of the semiconductor device.

What is claimed is:

1. A method for manufacturing a semiconductor device comprising:
forming an interlayer dielectric film having a through-hole on a first interconnection pattern;
depositing a via plug filling said through-hole and an interconnection layer on said interlayer dielectric film in a single step;
polishing a top surface of said interconnection layer;
forming an antireflection film on said polished surface of said interconnection layer; and
patterning said antireflection film and said polished interconnection layer to form a second interconnection pattern.

2. The method according to claim 1, wherein said depositing includes depositing a seed layer at a substrate temperature of 350 degrees C. or lower, and depositing on said seed layer a conductive film including aluminum (Al) by using a reflow sputtering technique.

3. The method according to claim 2, wherein said seed layer depositing includes depositing Al or an Al alloy by using a sputtering technique or a CVD technique.

4. The method according to claim 1, further comprising, between said interlayer dielectric film forming and said depositing, depositing a barrier metal layer within said through-hole.

5. The method according to claim 1, wherein said first interconnection pattern includes thereon another antireflection film, and said another antireflection film is removed at a bottom portion of said through-hole.

6. The method according to claim 4, wherein said barrier metal layer includes at least a TiN film.

7. The method according to claim 1, wherein said interlayer dielectric film forming consecutively comprises: depositing said interlayer dielectric film; etching a top portion of said interlayer dielectric film by an isotropic etching step using a mask to form a first hole; and etching a bottom portion of aid interlayer dielectric film at a bottom of said first hole, by an anisotropic etching technique using said mask, to from said through-hole.

8. The method according to claim 1, further comprising, between said interlayer dielectric film forming and said depositing, forming a sidewall film on a sidewall of said through-hole.

9. The method according to claim 1, wherein said first and second interconnection patterns each include an AlCu film.

10. The method according to claim 1, wherein said antireflection film includes TiN.

11. A semiconductor device comprising:
a first interconnection pattern overlying a semiconductor substrate;
an interlayer dielectric film having a through-hole through which a portion of said first interconnection pattern is exposed;
a second interconnection pattern formed on said interlayer dielectric film and including a via plug filling said through-hole, said second interconnection pattern having a polished top surface; and
an antireflection film formed on said second interconnection pattern.
